(19) United States
(12) Patent Application Publication
(10) Pub. No.: US 2026/0331207 A1
(43) Pub. Date: Oct. 22, 2026

(54) Computing Device Component Health

(71) Applicant: Microsoft Technology Licensing, LLC, Redmond, WA (US)

(72) Inventors: Samuel Chelsae KNIGHT, Portland, OR (US); Vishwas Reddy PULUGU, Portland, OR (US)

(73) Assignee: Microsoft Technology Licensing, LLC, Redmond, WA (US)

(21) Appl. No.: 19/180,735

(22) Filed: Apr. 16, 2025

(51) Int. Cl. G11C 29/50; G11C 5/04

(52) U.S. Cl. CPC G11C 29/50; G11C 5/04

(57) ABSTRACT

The description relates to enhancing component and device reliability by analyzing stored margin data relating to the component. One example can obtain first margin data relating to a component from a first time and obtain second margin data relating to the component from a subsequent second time. The example can compare the first margin data to the second margin data to identify a change in a condition of the component.

### BACKGROUND

Computing devices have evolved into diverse form factors, including smartphones, notebook computers, servers, vehicles, internet of things (IoT) devices, TVs, etc. Computing device reliability depends on the condition of the device components, such as memory, processors, peripherals, etc. A failure of any one of these components can cause the device to fail and/or lead to unsatisfying outcomes, such as lost data and other inconveniences.

### SUMMARY

This patent relates to enhancing component and device reliability by analyzing stored margin data relating to the component. One example can obtain first margin data relating to a component from a first time and can obtain second margin data relating to the component from a subsequent second time. The example can compare the first margin data to the second margin data to identify a change in a condition of the component.

Another example relates to a system that includes a memory unit and storage persistently storing first margin data from physical layer training of the memory unit at a first time and second margin data from physical layer training of the memory unit at a subsequent second time.

The examples provided in this Summary are intended as a quick reference to some of the described concepts. This Summary is not intended to be exhaustive or limiting.

### BRIEF DESCRIPTION OF THE DRAWINGS

The Detailed Description is described with reference to the accompanying figures. In the figures, the left-most digit(s) of a reference number identifies the figure in which the reference number first appears. The use of similar reference numbers in different instances in the description and the figures may indicate similar or identical items.

FIGS. 1A-1D, 2, 4, and 5 illustrate example systems that can implement some of the present concepts in accordance with some implementations.

FIG. 3 illustrates example margin data that is consistent with some of the present concepts.

FIGS. 6 and 7 illustrate example flowcharts that can implement some of the present concepts in accordance with some implementations.

### DETAILED DESCRIPTION

This patent relates to enhancing reliability of computing devices. Device reliability is enhanced by increasing reliability of device components (hereinafter, ‘components’). Example components include memory, peripherals, processors, etc. The component reliability enhancement is achieved by storing or otherwise maintaining information that can be correlated to a condition of the component (e.g., health) and changes to the condition over time. This information can be in the form of ‘margin’ data of the device components. The margin data is obtained and stored at different points in the life of the component. The stored margin data from different points in time can be analyzed to identify changes to the device.

Margin data relates to the status (e.g., health) of the components. Changes to the margin data can reflect changes to the health of the components. Thus, storing and comparing margin data during the life of the component allows a condition (e.g., health) of the component to be tracked over time. Further, storing and comparing this margin data allows the present implementations to make predictions about the future health of the components. These predictions can provide the basis of a technical solution that allows actions to be proactively taken to avoid component failures and hence device failures.

Briefly, components are connected via physical layer interfaces on a substrate (e.g., a motherboard). The physical (PHY) layer interface allows the components to communicate with other components on the motherboard. The physical layer interface relates to pins and traces that carry signal, power, and ground connections.

Component testing or training (e.g., PHY layer testing) produces margin data. The margin data is indicative of the state of the component and the physical layer interface. The margin data relates to signal integrity between the component and the motherboard. The margin data also relates to timing and synchronization of signals to and from the component. The present concepts store the margin data from multiple instances during the life of the component. The present concepts then provide a technical solution to identify a condition (e.g., health) of the component over time by comparing the stored margin data. Identifying condition changes allows actions to be taken before component failure, and hence device failure, thereby enhancing device reliability.

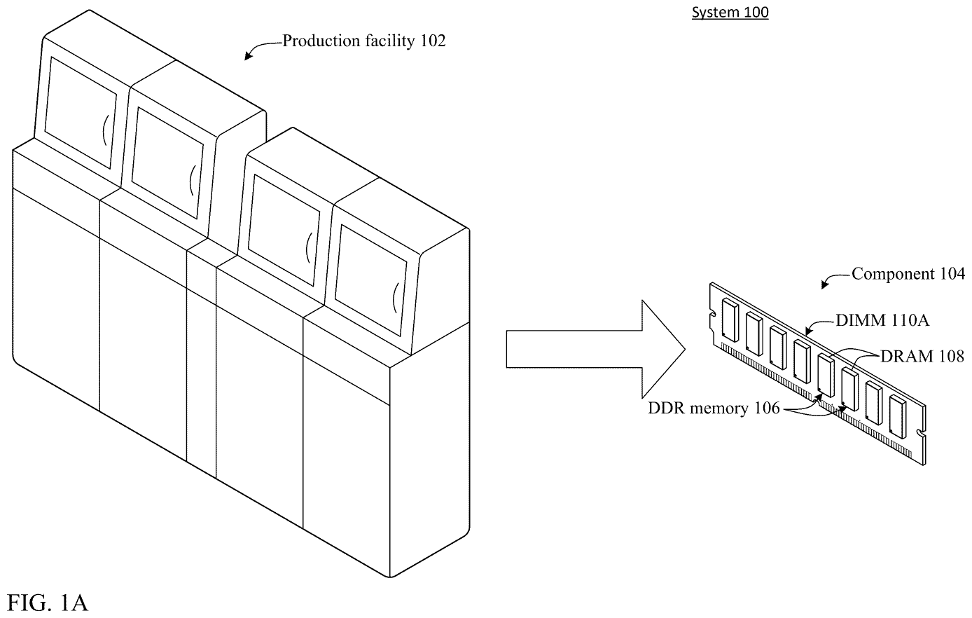

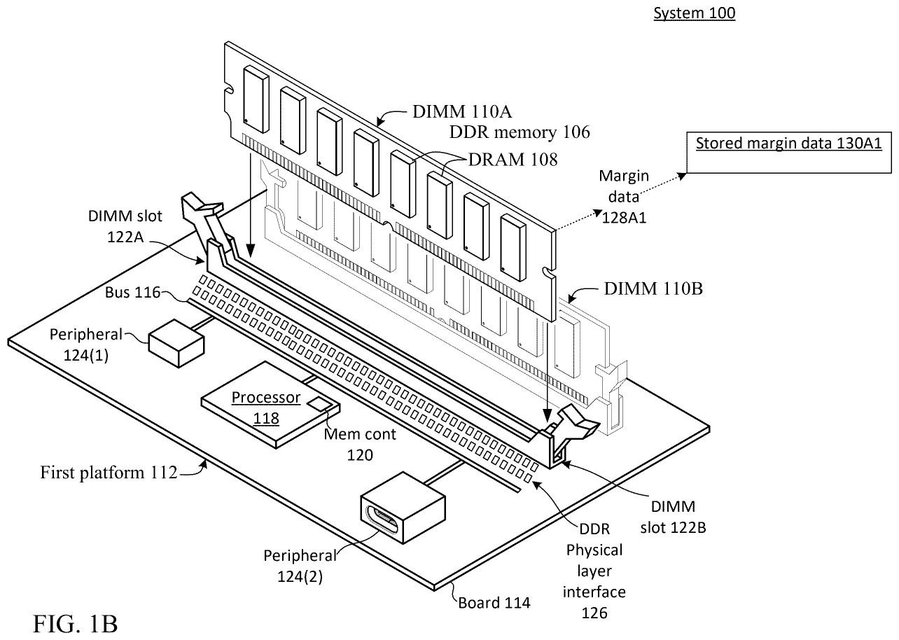

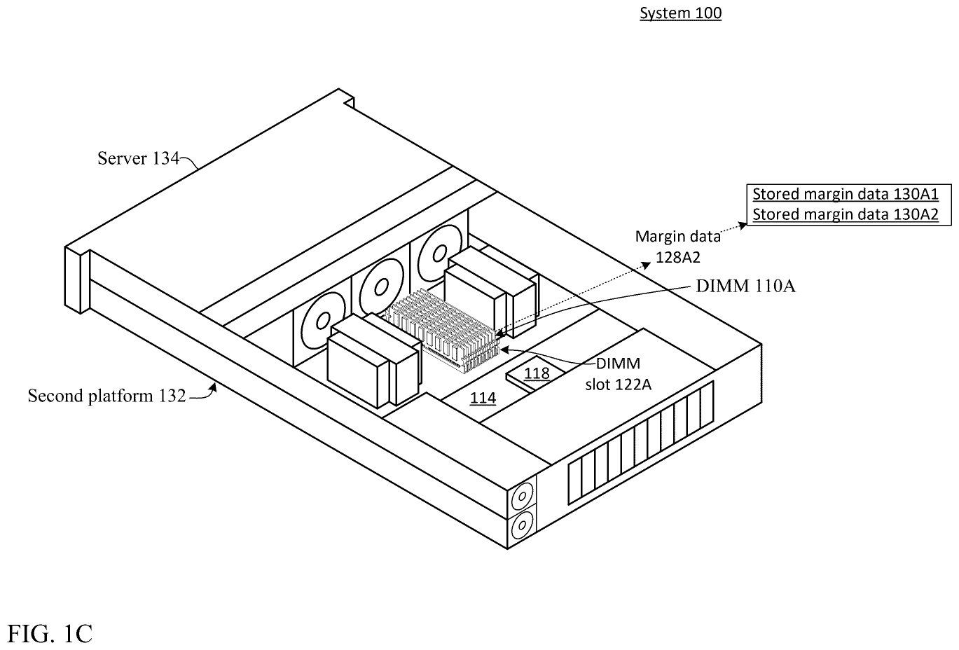

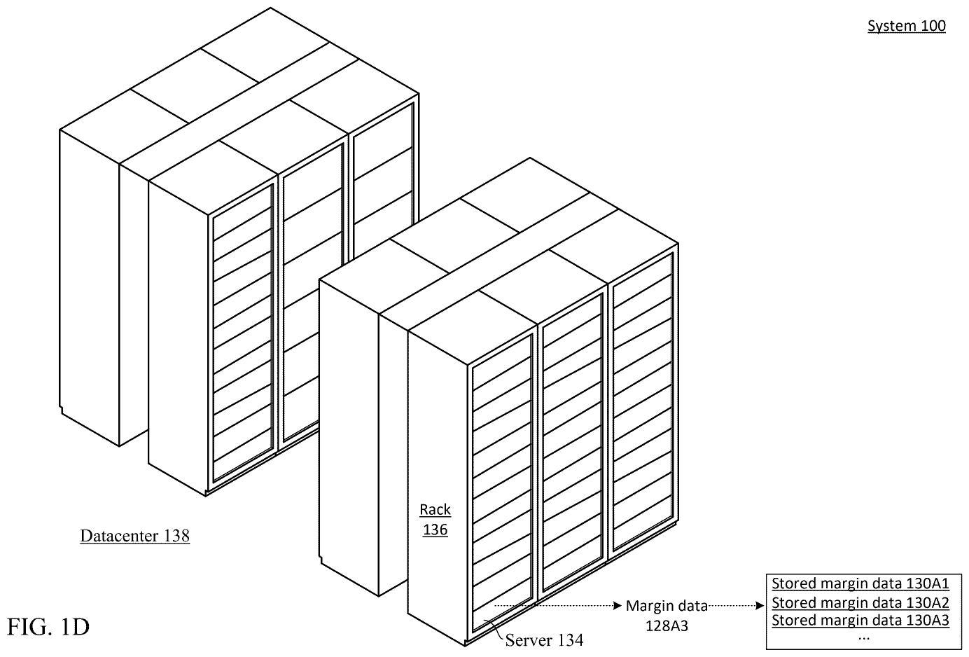

FIGS. 1A-1D collectively show example system 100, which can implement the present margin data storage and analysis concepts.

FIG. 1A shows a production facility 102 producing a component 104. In this example, the component 104 is a memory unit 106 in the form of dynamic random access memory (DRAM) 108. The DRAM 108 are incorporated into a dual in-line memory module (DIMM) 110A. The DIMM can be viewed as a package that physically holds and electrically supports the DRAM. The description that follows is applicable to other types of components and/or other types of memory units. In this example, the DIMM 110A includes eight DRAM 108, only two of which are specifically designated. The DIMM may include other numbers of DRAM. The DRAM 108 and/or the DIMM 110A can be tested to determine whether they conform to design parameters. This testing is called margin testing or training and is discussed below relative to FIG. 1B. The margin training can be analogized to calibration of signals into and out of the component.

FIG. 1B shows the DIMM 110A and a first platform 112. In this case, the first platform 112 is manifest as a test platform. Platforms have various components and configurations. One advantage of the test platform is that the number of variables can be reduced. Proper functioning of all aspects of the test platform including the conductors and all components besides the component being tested can be verified in advance so that the only variables are the component to be tested and the connections to the component to be tested. For instance, if the component to be tested is the DIMM, then all other components can be pretested with multiple DIMMS of known qualities to establish a baseline. Thus, expected margin training parameters can be known in advance for the DIMM under test.

The illustrated first platform 112 is representative and includes a board 114, a bus 116, a processor 118, a memory controller 120, DIMM slots 122, and/or other components, such as peripherals 124. A DDR physical layer interface 126 connects the bus 116 and the DIMM slots 122. In the illustrated example, the first platform 112 includes two DIMM slots 122 for testing two DIMMs 110. DIMM 110A is shown approaching DIMM slot 122A and DIMM 110B is shown positioned in DIMM slot 122B.

As mentioned above, DDR physical layer interface 126 connects the DIMMs 110 and the first platform 112. DDR physical (PHY) layer training (e.g., margin training or testing) can be performed while the DIMM 110 is part of the first platform 112. The margin training produces margin data 128A. In the illustrated configuration, the margin training can be controlled by the memory controller 120.

Margin training can be performed in various scenarios. One of the more common scenarios is system (e.g., platform) start (e.g., boot up). Thus, memory controller 120 will cause margin training to be performed upon powering on and/or restart of the first platform 112. Traditionally, each time margin training is performed, the previous margin data is lost.

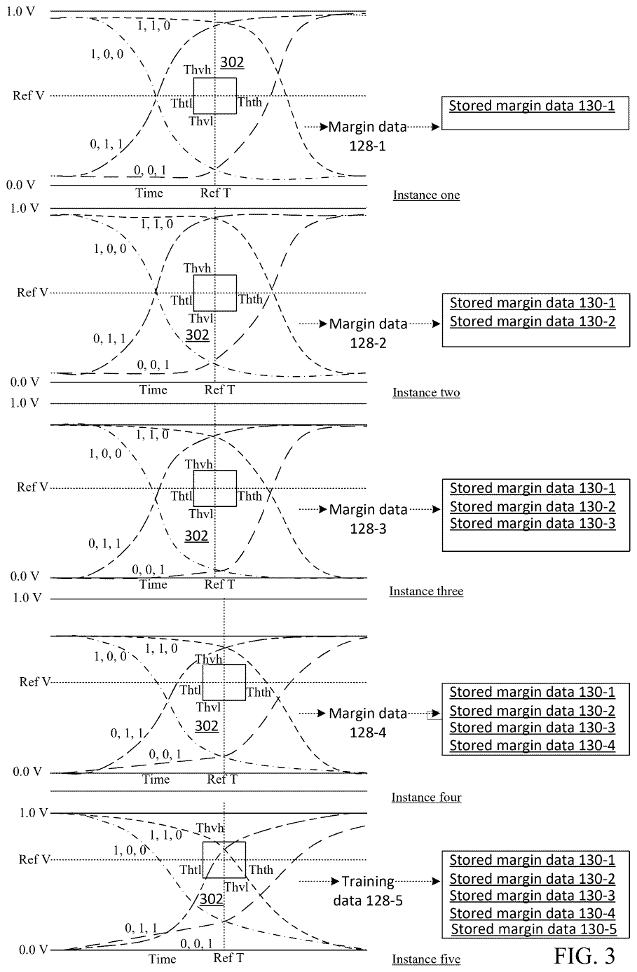

The margin data 128A indicates how the individual DRAM and/or the overall DIMM is functioning on the first platform 112 at the time of the margin training. Briefly, margin data relates to timing and voltage margins, among other parameters. Example margin data is illustrated and described below relative to FIG. 3. If the margin data 128A is outside of tolerances, the component (in this case the DIMM 110 and/or the DRAM 108) can be investigated. For instance, faulty margin data (e.g., outside of tolerances) can be caused by a defective component or the faulty margin data can be caused by other factors. For example, a defective component that includes multiple faulty circuits will produce margin data that is outside tolerances.

In another example, the faulty margin data can be caused by bad electrical connections between the component and the platform. For instance, foreign matter could be present in the connections between the DIMM 110A and the DIMM slot 122A that is preventing normal (e.g., expected) electrical connections. These factors can be investigated and if the problem lies with the component, the component can be repaired or discarded. The repaired or replacement DIMM can be installed and memory training can be performed again. As mentioned above, traditionally each time memory training is performed the previous training data is lost. Thus, the margin data provides a snapshot of the state of the component at the time of testing, but in isolation does not provide any insight into the condition of the component compared to previous points where margin testing was performed. Further, the margin data for one instance, in isolation, is not indicative of future changes in the condition of the component.

However, the present concepts include a recognition that comparing margin data gathered at various margin training points can detect condition changes and predict future condition changes. Toward that end, the present description provides a technical solution that persistently stores margin data 128 for an individual component from multiple instances of margin training as stored margin data 130.

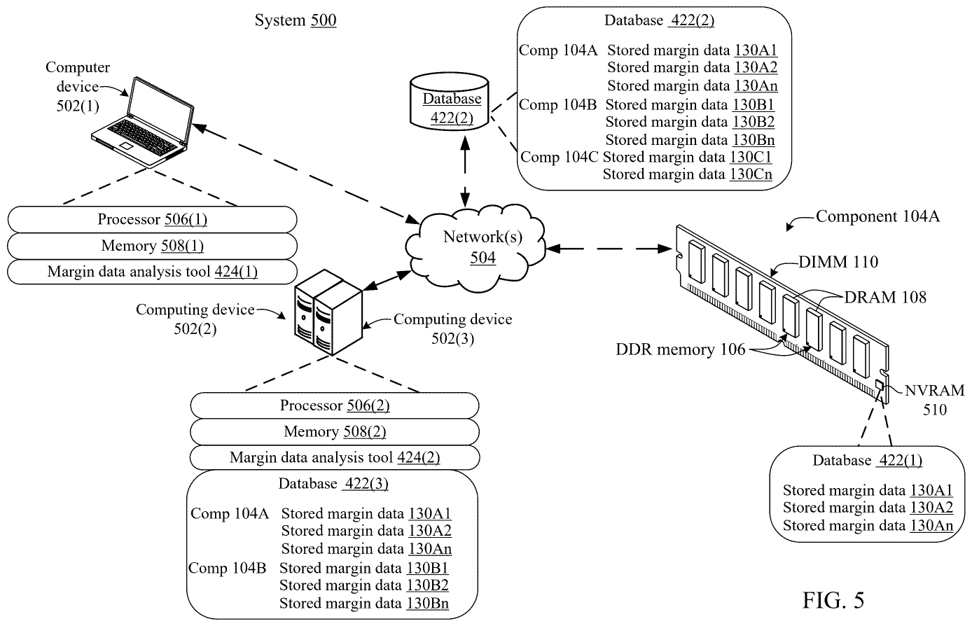

During margin training, margin data 128 is affected by various parameters, such as the temperature that the margin testing was performed at for the component, type of bus, type of memory controller, platform information, such as information about other components (e.g., system on a chip (SoC)) identification (id) (e.g., a unique identifier), processor type and id, etc. These parameters can be included in the stored margin data 130. The stored margin data 130 can be stored on the component 104 (e.g., on the DIMM 110), on the platform, and/or remotely. These aspects are described in more detail below relative to FIG. 5.

Assume for purposes of explanation, that the margin data 128A1 indicates DIMM 110A is within tolerances and as such is functioning properly on the first platform 112. As such, the margin data 128A1 is stored as stored margin data 130A1. The DIMM 110A is now ready for use.

FIG. 1C shows the DIMM 110A installed on a second platform 132, which is manifest as a server 134. Similar to the first platform, the second platform 132 includes board 114 that has processor 118 and DIMM slots 122 positioned on it. While not specifically designated the board 114 also includes a bus, peripherals, and a physical layer interface similar to first platform 112. In this case, there are ten DIMM slots and ten DIMMs. The description highlights DIMM slot 122A and DIMM 110A, but is equally applicable to the other DIMMs and DIMM slots. As part of the initial device testing, the device will be powered on, which as described above, will cause margin training to be performed on the DIMM 110A. This margin training will generate margin data 128A2. The margin data 128A2 will be stored as stored margin data 130A2. Assume for purposes of explanation, that the margin data 128A2 is within tolerances and that the remainder of the second platform 132 also passes quality testing. The second platform 132 (e.g., server 134) is now ready for deployment.

FIG. 1D shows the server 134 deployed in rack 136 in a datacenter 138 with other servers. The DIMM and other components are not visible in this view but remain as shown in FIG. 1C. When the server 134 is powered up, margin training is performed that produces margin data 128A3 that is stored as stored margin data 130A3. Further, each time the server 134 is restarted, additional margin training will produce additional margin data 128A4, etc. and stored margin data 130A4, etc.

Traditionally, the server 134 would be operated in the rack until the server failed or reached a predefined age for replacement. In contrast, the present concepts provide a technical solution that dynamically identifies changes in the health of the DIMM and/or predicts future changes in the health of the DIMM by comparing the stored margin data 130A obtained at different times. The comparison can identify that a condition of the DIMM has changed, is changing and/or likely will change in the future. This identification is accomplished with real data from the individual DIMM. This is in contrast to traditional techniques which utilize the average age of component failure, not information from the individual component gathered during its operational life.

For purposes of explanation, assume that comparison of the stored margin data 130A1-130A3 identifies a changing condition in the DIMM with an associated probability of DIMM failure of less than 10% in the next 30 days, but a 50% chance of failure between 31 days and 60 days. This information allows time for actions to be taken before the component is likely to fail. For instance, within 30 days, the data on the DIMM could be backed up, and the server could be replaced. This solution allows the server to operate as long as possible so as not to waste resources, but not so long that component and device failure causes workload interruptions and/or data loss.

Note that while in the illustrated example, the second platform 132 is manifest as server 134, the second platform 132 could be manifest as a notebook computer, smartphone, desktop computer, internet of things (IoT) device, etc. Further, as mentioned above, for purposes of explanation, the above example is focused on memory (e.g., DRAM and DIMM). However, the present concepts are applicable to other components of the device.

Device reliability is paramount when the device is expected to perform workloads. Component failure causes device failure. The ability to track the condition of the components allows proactive actions to be taken to avoid failure scenarios, such as workload failure and/or loss of user data. Toward this end, the present concepts can systematically cause additional margin data to be obtained from the device. For instance, some of the present implementations may cause the device to undergo restarts at times that will not affect device performance, such as times with low or no workload.

As noted above, the restart will cause the platform to undergo margin testing of the components to produce additional margin data. For instance, these implementations could restart one server at a time so that a majority of the servers are available to perform the workload at any one time. Alternatively or additionally, some implementations may cause the device to restart during idle times, such as during the middle of the night, when the device is not contributing to any workload or the device's portion of the workload can be transferred temporarily to another device during the restart. This allows the present concepts to store margin data relating to a component over time. For instance, all the stored margin data could show the margin data satisfying a threshold, but comparing the margin data could indicate that the margin data is trending toward the threshold.

The present concepts can use the comparison to make a prediction about a time and likelihood of a future component failure. For instance, while the stored margin data at each sampled time is within the threshold, the present concepts allow a prediction to be made that the component has for instance, a 50 percent likelihood of failure in the next 30 days and a 75 percent likelihood of failure within the next 60 days, for example. This allows proactive actions to be taken to avoid device failure. For instance, the data on the DIMM could be transferred to another server and the server could be taken out of service. Thus, the user experience is enhanced in that the user does not experience any data loss or other inconvenience. The server could then be repaired, such as by replacing the DIMM and placed back in service or replaced with another server. Thus, the present concepts provide a technical solution that predicts component failure and allows action to be proactively taken to avoid device failures, data loss, and a compromised user experience.

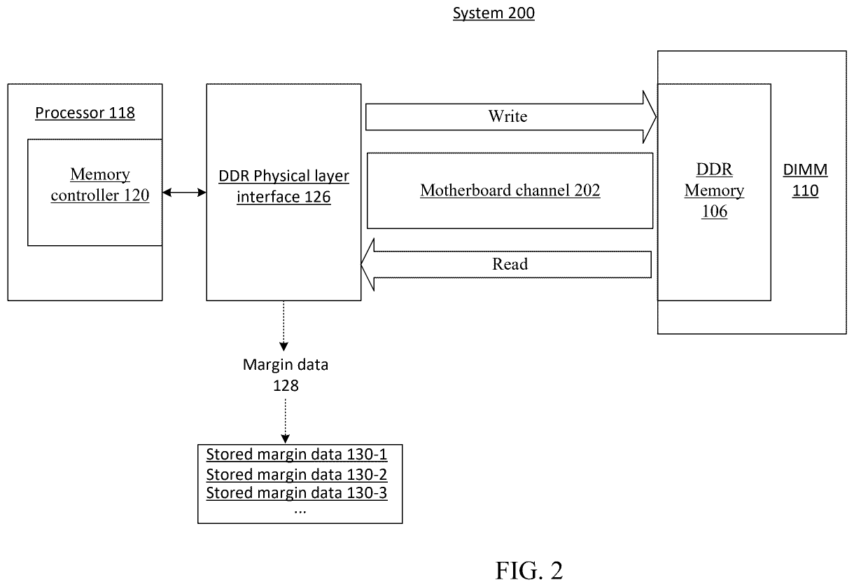

FIG. 2 shows a system 200 representing a block diagram of an example DDR physical layer interface 126. (DDR stands for double data rate.) In this case, the DDR physical layer interface 126 represents a motherboard channel 202 between the memory controller 120 and processor 118 on one side and the DDR memory 106 on the other side. As in the example shown in FIGS. 1A-1D, the DDR memory 106 may be integrated into a DIMM 110. Note the description relates to other types of memory units, and other types of components.

Motherboard channel 202 conveys write commands from the processor 118 to the DDR memory 106 and read commands from the DDR memory 106 to the processor 118. The memory controller 120 can cause margin training to be performed on the DDR physical layer interface 126 to ensure these read and write commands are completed successfully. Margin training dynamically adjusts platform parameters, such as time and voltage parameters to promote successful read and write operations. Margin training is described in more detail below relative to FIG. 3. The margin training produces margin data 128 that is persistently stored as stored margin data 130.

FIG. 3 shows margin data 128 associated with PHY layer training of individual DRAM 108 introduced above relative to FIG. 1A. FIG. 3 shows margin data 128 obtained from margin training at five different times represented as Instance one through Instance five. Each instance shows a graph of margin data 128 with voltage on the vertical axis and time on the horizontal axis. Four signals are shown in the graph representing values of (1, 1, 0), (1, 0, 0), (0, 1, 1), and (0, 0, 1). These four lines can define the bounds of a ‘margin eye’ 302. A reference voltage (Ref V) is represented as a horizontal line. A reference time (Ref T) is represented by a vertical line.

For purposes of discussion four thresholds (Th) have been added to the representations that are not part of the margin data. The thresholds are high voltage (Thvh), low voltage (Thvl), time high (Thth), and time low (Thtl). The thresholds can represent acceptable variation where the memory still functions properly. If variation exceeds any of the thresholds, memory errors and failure will occur. Thus, if the thresholds remain within the margin eye 302, the memory will function properly, if not, failure will occur, such as ‘1’ values will be written in memory as ‘0’ values, or vice versa, for instance.

Margin training attempts to “center” the margin eye 302 (or signal eye) at boot time. Margins can indicate how much a system (e.g., platform) can tolerate in terms of temperature, voltage, process, and/or aging effects, among others. Since the margin is a product of every component in the signal chain, the test pattern, and the environment, each system will have varying margins and hence margin data 128. Besides the trained values, the PHY training algorithms output a summary table of margin results that can be read from the system post-boot. This data set can be considered as part of the margin data 128 and included in the stored margin data 130.

Assume for purposes of explanation that the margin data 128-1 of Instance one is obtained from the scenario of FIG. 1B where DDR memory in the form of DRAM 108 is positioned on first (test) platform 112. Margins should be relatively large in this known ‘good’ test platform. Some or all of this margin data 128-1 is stored as stored margin data 130-1 as introduced above. Similarly, assume that margin data 128-2 of Instance two is obtained from the scenario of FIG. 1C where DRAM 108 is positioned on second (production) platform 132 (e.g., server). The margins should not have a large delta from those of Instance one. Some or all of this margin data 128-2 is stored as stored margin data 130-2 as introduced above.

Further, assume that margin data 128-3 of Instance three is obtained from the scenario of FIG. 1D where the second platform 132 is installed in a rack and turned on. The margins should not have a large delta from those of Instance two. Some or all of this margin data 128-3 is stored as stored margin data 130-3 as introduced above. Further, assume that margin data 128-4 of Instance four is obtained from a scenario where the second platform is restarted during a period of low workload in the datacenter. The margins should not have a large delta from those of Instance three. Some or all of this margin data 128-4 is stored as stored margin data 130-4 as introduced above. Further, assume that Instance five is a future scenario that has not yet occurred.

Note that in each of these Instances one-four, the margin data 128 would indicate the condition of the DRAM 108 is acceptable. Traditionally the margin data 128 is lost as soon as margin training is complete. However, the present techniques persistently save the margin data 128 as saved margin data 130. This technical solution allows analysis and comparison of the saved (e.g., stored) margin data 130 from various times and platform configurations. This comparison provides an additional technical solution that can detect changes in the condition of the component and can make predictions about future conditions of the component. Some of these aspects are illustrated in FIG. 3.

As noted above, each of Instances one-four indicate acceptable component function when viewed in isolation. However, when the stored margin data of Instances one-four are compared to one another, a change in condition can be detected where the margin data is approaching the thresholds, specifically margin data is approaching the high voltage threshold (Thvh) and the delta of change compared to the previous margins is accelerating. This changing condition identified in the stored margin data 130 can be used as the basis for a prediction that the component (in this case DRAM 108) is going to fail in the future.

The changing condition of the component can even provide a basis for predicting when the failure will occur. In this example, the failure would occur at future Instance five. However, the inventive concepts provide a technical solution that detects this changing condition and allows actions to be taken to avoid the failure represented by future Instance five. For example, after Instance four, actions could be taken such as backing-up the data stored in the component to another device and removing the device from the rack for repair or disposal before the failure of Instance five ever occurs. Thus, the technical solution of margin data storing and comparing avoids the catastrophic consequences of component failure that would otherwise occur.

The diagnostic value of the stored margin data 130 can be further improved by increasing the granularity of the margins and strengths of the patterns used to collect the margin. For example, per rank margins can aid identification of a bad DIMM, but with per lane margins the present techniques can isolate an issue down to a specific DRAM on the DIMM. Increased pattern lengths will improve the quality and repeatability of the margin data, however this comes at the cost of increased boot time. Once these factors are balanced, consistency is a key factor of the value of the margin data. If the pattern changes, then the margins are no longer as readily comparable. A consistent project to project strategy will enhance the diagnostic nature of the results.

Note that the example margin data 128 illustrated and described relative to FIG. 3 is just some of the margin data that can be stored (e.g., stored margin data 130) for comparison purposes. Margin data 128 can be stored in graphical form, text form, numerical form, etc. Component health is a product of silicon design, manufacturing tolerances, platform design, memory module type, and/or external factors, such as supply voltage and temperature, and/or the effects of aging over time, among other parameters. Any or all of these parameters can be stored as stored margin data 130 or with the stored margin data and can be associated with the component (e.g., stored on the component) and/or stored with a unique identifier of the component.

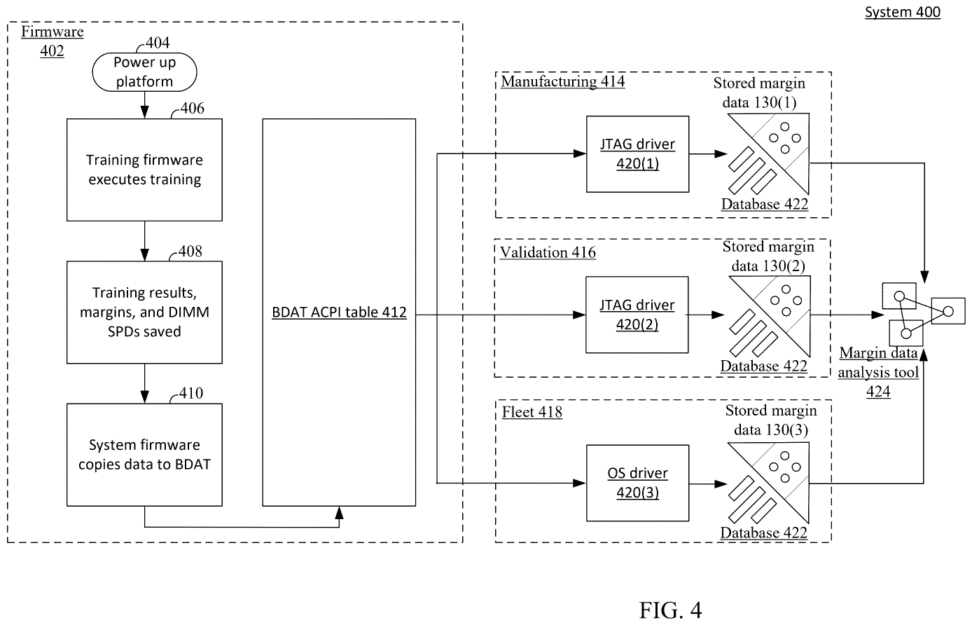

FIG. 4 shows an example system 400 configured to accomplish margin data collection and storage for components, such as memory, processors, etc. In this example, margin data collection is enabled by software or firmware 402 that operates relative to the platform on which the component is positioned. Example platforms are introduced in the description above relative to FIGS. 1A-1D. The software or firmware 402 may be stored and run on the platform. Alternatively or additionally, the software or firmware 402 may be remote and instructions may be sent to the platform for execution. The execution commences at platform power up or causes the platform to power up at 404. Component training firmware executes training on individual components at 406. The training results, margins, and component serial presence detection (SPDs) are saved at 408. In this example, the component is a DIMM. However, the component could be an individual DDR memory, such as an individual DRAM, a processor, peripheral, etc. At 410, the system or platform firmware copies this data to BIOS Data ACPI Table (BDAT) 412. (ACPI stands for advanced configuration and power interface. BIOS stands for basic input/output system.) Recall that this process is repeated in multiple scenarios, such as manufacturing 414 (e.g., testing of FIG. 1B), validation 416 (e.g., of FIG. 1C), and fleet 418 (e.g., FIG. 1D) and/or multiple times in individual scenarios (e.g., restarting of FIG. 1D). For instance, as mentioned above, devices (e.g., platforms) could be restarted at opportune times in the data center (or when an end user is not using a consumer device) to generate additional margin data.

Once the margin data 128 is in the BDAT table 412, there are further challenges depending on the operating system (OS). A driver 420 can be employed to read and process the margin data such that it can be output into a database 422 to be saved as stored margin data 130. In some cases, such as in manufacturing stage 414 and validation stage 416, the drivers 420(1) and 420(2) can be compliant with joint test action group (JTAG) guidelines. JTAG allows device programmer hardware to transfer data into internal non-volatile device memory, which supports database 422. In the production platform (e.g., the finished device, such as a server device) the driver 420(3) can be an operating system driver.

One challenge is that with every environment comes different tools and methodologies that margin data collection must be integrated with. A unified database 422 with all of the stored margin data 130 is difficult to build due to different security and technical requirements. Therefore, analysis tools or services 424 can be employed to consume from multiple data sources and reconcile any data format differences.

The present concepts enable collecting and storing margin data across the entire end-to-end of the component life cycle and take advantage of comparisons of the stored margin data to identify changes in the health of the component. Consistent and reliable margin data collection at different points in the component life cycle is a key to being able to predict and prevent downtime due to memory margin issues. Predicting failures early and constant monitoring of the stored margin data can dramatically improve system uptime and data center utilization, among other advantages.

The present implementations can be performed in various scenarios on various devices. FIG. 5 shows details of an example system 500 in which the present implementations can be employed, as discussed in more detail below. System 500 includes computing devices 502. In this case, the illustrated example computing devices include a notebook computer 502(1) and servers 502(2), and 502(3). As mentioned above, many different types of computing devices 502 are contemplated. Note also, the computing devices 502 can entail first and/or or second platforms 112 and 132, introduced relative to FIGS. 1B and 1C, respectively. The computing devices 502 can be coupled by a network 504.

The computing devices 502 include components 104 as introduced above. Processors 506 and memory 508 are examples of components 104. For purposes of explanation, component 104A is also shown in isolation.

Generally, the devices 502 may include processors 506, memory 508, and other components 104, as well as an instance of the margin data analysis tool 424, which as introduced above relative to FIG. 4. System 500 also includes several examples of database 422.

Database 422(1) is resident on component 104A on nonvolatile random access memory (NVRAM) 510 or other nonvolatile memory. In some implementations, NVRAM 510 is a small amount of nonvolatile memory, such as Flash memory, for database 422(1). In this case, database 422(1) contains stored margin data 130A that relates to the same component 104A on which the NVRAM 510 is positioned. Stated another way, the NVRAM 510 exists on the component to maintain stored margin data 130 for that component for the lifetime of the component. For instance, in the illustrated configuration, database 422(1) is manifest on component 104A to maintain stored margin data 130A1-130An that relates to component 104A. (The suffix ‘n’ in ‘130An’ represents that any integer number of stored margin data occurrences can be included). Thus, in this configuration, even if the component 104A is moved from one platform to another, the component maintains a record of margin data (e.g., stored margin data 130A) from each time margin testing is performed on the component over the lifetime of the component. Note also, that the stored margin data 130 on component 104A can relate to the DIMM 110 and/or the individual DDR memory units 106 making up the DIMM.

Computing device 502(1) offers an alternative configuration. Computing device 502(1) includes components for which margin data can be maintained/persisted, such as processor 506(1) and memory 508(1). However, in this case, the stored margin data 130 is maintained on remote database 422(2). Computing device 502(1) includes an instance of margin data analysis tool 424(1). The margin data analysis tool 424(1) can upload stored margin data 130 for its components when margin testing is performed. The margin data analysis tool 424(1) can also access and analyze the stored margin data to identify changes in conditions of the components of computing device 502(1).

Computing devices 502(2) and 502(3) represent servers in a datacenter. These computing devices show another configuration where the device includes both an instance of the margin data analysis tool 424(2) and the database 422(3). The margin data analysis tool 424(2) and the database 422(3) could both be on the same computing device or could be distributed within the datacenter. In either case, the margin data analysis tool 424(2) can compare stored margin data for individual components over time. This comparison can be done both on an individual component in isolation (e.g., does a comparison of the stored margin data from different times indicate a condition change). This comparison can also be done relative to other similar components, (e.g., is the margin data of this individual component changing in a way that is different from the margin data of other comparable components on other devices). In either case, the margin data analysis tool 424(2) can take actions to avoid component failure. For instance, the margin data analysis tool 424(2) could detect a condition change that indicates a high probability of component failure. The margin data analysis tool 424(2) could transfer data from the component to other components (e.g., from the device the component is on to another device) and take the device offline or schedule maintenance. In other cases, the margin data analysis tool 424(2) could generate notices for service technicians and allow the technicians to determine how to handle the detected component condition change.

In some implementations, the margin data analysis tools 424 can employ or operate cooperatively with machine learning or artificial intelligence. For instance, some implementations can employ machine learning or artificial intelligence to compare stored margin data from different times to identify condition changes in the component. For example, an artificial intelligence (AI) model could be trained with labeled margin data from various components. The trained AI model could then monitor stored margin data for the devices in the datacenter to identify component condition changes.

In another implementation, the AI model could be trained on stored margin in a datacenter operated in a traditional manner where devices are run until they fail. However, during this time margin data would be stored for the devices. The AI model could ingest stored margin data from the components of the device of the datacenter. As mentioned, the computing devices could be managed in a traditional manner (e.g., allowed to operate until failure). The AI model could use the end result (e.g., the failure health condition) as the labelled data and compare the stored margin data leading up to the failure to learn patterns in the stored margin data associated with component health. Once the accuracy of the AI model meets a desired threshold, the AI model could analyze margin data and stored margin data for the components going forward and detect condition changes that have happened, are happening, and/or are likely to happen in the future.

Regardless of the training method, once trained, the AI model could monitor and compare stored margin data for the components in the devices in the datacenter and/or components in other computing devices. The trained AI model could enhance datacenter reliability (e.g., operational performance) by identifying component failure before it happens.

Further, the trained AI model could compare models of components that it identifies as more reliable than other models of components. The AI model could perform this in isolation (e.g., Brand A model B memory is more reliable than Brand C model D memory). The AI model could also perform this for sets of components (e.g., Brand A model B memory in combination with Brand E model F processor is more reliable than either Brand A model B memory or Brand C model D memory in combination with Brand G model H processor).

The term “computing device” as used herein can mean any type of device that has some amount of hardware processing capability and/or hardware storage/memory capability. Processing capability can be provided by one or more hardware processors (e.g., hardware processing units/cores) that can execute computer-readable instructions to provide functionality. Computer-readable instructions and/or data can be stored on storage, such as storage/memory and/or the database. The term “system” as used herein can refer to a single device, multiple devices, etc.

Memory 508 (e.g., storage resources) can be internal or external to the respective devices with which they are associated. The memory 508 can include any one or more of volatile or non-volatile memory, hard drives, flash storage devices, and/or optical storage devices (e.g., compact discs, digital versatile discs, etc.), among others. As used herein, the term “computer-readable media” can include signals. In contrast, the term “computer-readable storage media” excludes signals. Computer-readable storage media includes “computer-readable storage devices.” Examples of computer-readable storage devices include volatile storage media, such as RAM, and non-volatile storage media, such as hard drives, optical discs, and flash memory, among others.

In some cases, the devices are configured with a general-purpose hardware processor and storage resources. In other cases, a device can include a system on a chip (SOC) type design. In SOC design implementations, functionality provided by the device can be integrated on a single SOC or multiple coupled SOCs. One or more associated processors can be configured to coordinate with shared resources, such as memory, storage, etc., and/or one or more dedicated resources, such as hardware blocks configured to perform certain specific functionality. Thus, the term “processor,” “hardware processor” or “hardware processing unit” as used herein can also refer to central processing units (CPUs), graphical processing units (GPUs), controllers, microcontrollers, processor cores, or other types of processing devices suitable for implementation both in conventional computing architectures as well as SOC designs.

Alternatively, or in addition, the functionality described herein can be performed, at least in part, by one or more hardware logic components. For example, and without limitation, illustrative types of hardware logic components that can be used include field-programmable Gate Arrays (FPGAs), application-specific Integrated Circuits (ASICs), application-specific standard products (ASSPs), system-on-a-chip systems (SOCs), complex programmable logic devices (CPLDs), etc.

In some configurations, any of the modules/code discussed herein can be implemented in software, hardware, and/or firmware. In any case, the modules/code can be provided during manufacture of the device or by an intermediary that prepares the device for sale to the end user. In other instances, the end user may install these modules/code later, such as by downloading executable code and installing the executable code on the corresponding device.

Also note that devices may have input and/or output functionality. For example, computing devices can have various input mechanisms such as keyboards, mice, touchpads, voice recognition, gesture recognition (e.g., using depth cameras such as stereoscopic or time-of-flight camera systems, infrared camera systems, red-green-blue camera systems or using accelerometers/gyroscopes, facial recognition, etc.) and/or touch displays. Devices can also have various output mechanisms such as speakers, printers, displays, etc. In further implementations, Internet of Things (IoT) devices can be used in place of or in addition to other types of computing devices discussed herein.

Also note that the devices described herein can function in a stand-alone or cooperative manner to implement the described techniques. For example, the methods and functionality described herein can be performed on a single computing device and/or distributed across multiple computing devices that communicate over network(s) 504. Without limitation, network(s) 504 can include one or more local area networks (LANs), wide area networks (WANs), the Internet, and the like.

### Machine Learning Overview

There are various types of machine learning frameworks that can be trained to perform a given task. Support vector machines, decision trees, and neural networks are just a few examples of machine learning frameworks that have been used in a wide variety of applications, such as image processing and natural language processing. Some machine learning frameworks, such as neural networks, use layers of nodes that perform specific operations.

In a neural network, nodes are connected to one another via one or more edges. A neural network can include an input layer, an output layer, and one or more intermediate layers. Individual nodes can process their respective inputs according to a predefined function, and provide an output to a subsequent layer, or, in some cases, a previous layer. The inputs to a given node can be multiplied by a corresponding weight value for an edge between the input and the node. In addition, nodes can have individual bias values that are also used to produce outputs. Various training procedures can be applied to learn the edge weights and/or bias values. The term “parameters” when used without a modifier is used herein to refer to learnable values such as edge weights and bias values that can be learned by training a machine learning model, such as a neural network.

A neural network structure can have different layers that perform different specific functions. For example, one or more layers of nodes can collectively perform a specific operation, such as pooling, encoding, or convolution operations. For the purposes of this document, the term “layer” refers to a group of nodes that share inputs and outputs, e.g., to or from external sources or other layers in the network. The term “operation” refers to a function that can be performed by one or more layers of nodes. The term “model structure” refers to an overall architecture of a layered model, including the number of layers, the connectivity of the layers, and the type of operations performed by individual layers. The term “neural network structure” refers to the model structure of a neural network. The term “trained model” and/or “tuned model” refers to a model structure together with parameters for the model structure that have been trained or tuned. Note that two trained models can share the same model structure and yet have different values for the parameters, e.g., if the two models are trained on different training data or if there are underlying stochastic processes in the training process.

There are many machine learning tasks for which there is a relative lack of training data. One broad approach to training a model with limited task-specific training data for a particular task involves “transfer learning.” In transfer learning, a model is first pretrained on another task for which significant training data is available, and then the model is tuned to the particular task using the task-specific training data.

The term “pretraining,” as used herein, refers to model training on a set of pretraining data to adjust model parameters in a manner that allows for subsequent tuning of those model parameters to adapt the model for one or more specific tasks. In some cases, the pretraining can involve a self-supervised learning process on unlabeled pretraining data, where a “self-supervised” learning process involves learning from the structure of pretraining examples, potentially in the absence of explicit (e.g., manually-provided) labels. Subsequent modification of model parameters obtained by pretraining is referred to herein as “tuning.” Tuning can be performed for one or more tasks using supervised learning from explicitly-labeled training data, in some cases using a different task for tuning than for pretraining.

### Terminology

For the purposes of this document, the term “language model” refers to any type of automated agent that communicates via natural language. For instance, a language model can be implemented as a neural network, e.g., a decoder-based generative language model such as versions of ChatGPT, Gemini, Chameleon, a long short-term memory model, etc. The term “generative model,” as used herein, refers to a machine learning model employed to generate new content. Generative models can be trained to predict items in sequences of training data. When employed in inference mode, the output of a generative model can include new sequences of items that the model generates. Thus, a “generative language model” is a model that can generate new sequences of text given some input prompt, e.g., a query potentially with some additional context.

The term “prompt,” as used herein, refers to input text provided to a generative language model that the generative language model uses to generate output text. A prompt can include a query, e.g., a request for information from the generative language model. A prompt can also include context, or additional information that the generative language model uses to respond to the query.

The term “data health issue” refers to any characteristic of a dataset that could impact results of processing that dataset. Examples of data health issues include the presence of corrupted data, erroneous data, improperly formatted data, statistical outliers, etc. The term “data evaluation action” refers to any action performed on a dataset that can identify a data health issue. A “data evaluation plan” is one or more data evaluation actions that can be performed on a given dataset. A “data cleaning action” is an action that attempts to improve data quality by correcting at least one data health issue, e.g., by removing an entry or value from a dataset, changing a value in the dataset to a different value, etc.

A “summary” of a dataset refers to a representation of the dataset as a whole. A summary of a dataset can include data types of fields of the dataset, statistical information for fields of the dataset, and/or annotations of individual fields of the dataset, a set of fields of the dataset, or the dataset as a whole. A “data health score” refers to any metric that characterizes the presence of data health issues in a dataset. A “severity dictionary” is one or more indications of how severe a particular type of data health issue is when present in a dataset. For instance, a severity dictionary can indicate that missing values are relatively more severe than statistical outliers, and can include weights designating the relative severity of each.

The term “machine learning model” refers to any of a broad range of models that can learn to generate automated user input and/or application output by observing properties of past interactions between users and applications. For instance, a machine learning model could be a neural network, a support vector machine, a decision tree, a clustering algorithm, etc. In some cases, a machine learning model can be trained using labeled training data, a reward function, or other mechanisms, and in other cases, a machine learning model can learn by analyzing data without explicit labels or rewards. The term “user-specific model” refers to a model that has at least one component that has been trained or constructed at least partially for a specific user. Thus, this term encompasses models that have been trained entirely for a specific user, models that are initialized using multi-user data and tuned to the specific user, and models that have both generic components trained for multiple users and one or more components trained or tuned for the specific user. Likewise, the term “application-specific model” refers to a model that has at least one component that has been trained or constructed at least partially for a specific application.

The term “pruning” refers to removing parts of a machine learning model while retaining other parts of the machine learning model. For instance, a large machine learning model can be pruned to a smaller machine learning model for a specific task by retaining weights and/or nodes that significantly contribute to the ability of that model to perform a specific task, while removing other weights or nodes that do not significantly contribute to the ability of that model to perform that specific task. A large machine learning model can be distilled into a smaller machine learning model for a specific task by training the smaller machine learning model to approximate the output distribution of the large machine learning model for a task-specific dataset.

### Example Decoder-Based Language Model

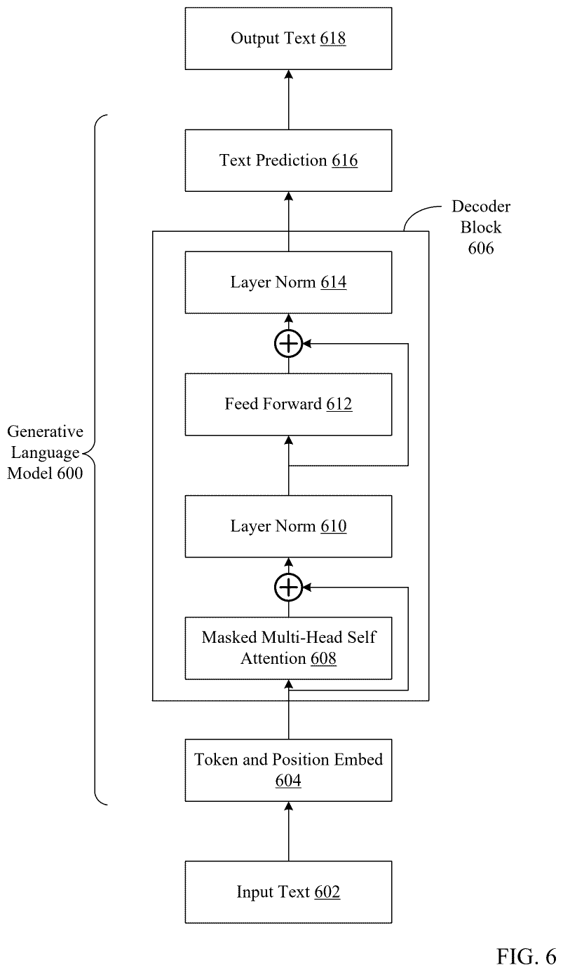

FIG. 6 illustrates an example generative model, such as generative language model 600 that can be employed using the disclosed implementations. Generative language model 600 is an example of a machine learning model that can be used to perform one or more natural language processing tasks that involve generating text, as discussed more below. For the purposes of this document, the term “natural language” means language that is normally used by human beings for writing or conversation.

Generative language model 600 can receive input text 602, e.g., a prompt from a user. For instance, the input text can include words, sentences, phrases, or other representations of language. The input text can be broken into tokens and mapped to token and position embeddings 604 representing the input text. Token embeddings can be represented in a vector space where semantically-similar and/or syntactically-similar embeddings are relatively close to one another, and less semantically-similar or less syntactically-similar tokens are relatively further apart. Position embeddings represent the location of each token in order relative to the other tokens from the input text.

The token and position embeddings 604 are processed in one or more decoder blocks 606. Each decoder block implements masked multi-head self-attention 608, which is a mechanism relating different positions of tokens within the input text to compute the similarities between those tokens. Each token embedding is represented as a weighted sum of other tokens in the input text. Attention is only applied for already-decoded values, and future values are masked. Layer normalization 610 normalizes features to mean values of 0 and variance to 1, resulting in smooth gradients. Feed forward layer 612 transforms these features into a representation suitable for the next iteration of decoding, after which another layer normalization 614 is applied. Multiple instances of decoder blocks can operate sequentially on input text, with each subsequent decoder block operating on the output of a preceding decoder block. After the final decoding block, text prediction layer 616 can predict the next word in the sequence, which is output as output text 618 in response to the input text 602 and also fed back into the language model. The output text can be a newly-generated response to the prompt provided as input text to the generative language model.

### Example Methods

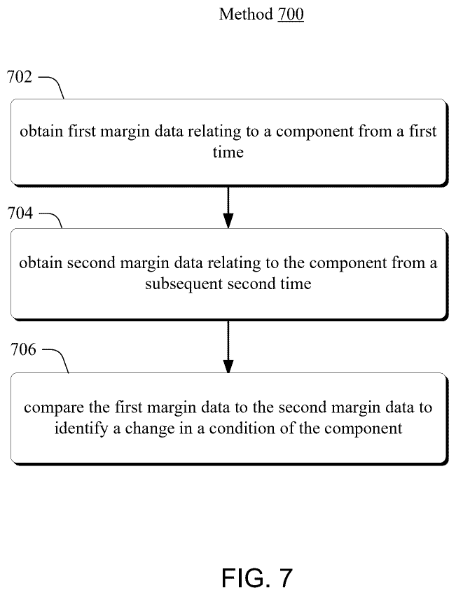

Several implementations are described in detail above. FIG. 7 shows an example margin data analysis method or technique 700.

Block 702 can obtain first margin data relating to a component from a first time. For instance, the method can obtain and store the first margin data. Alternatively, the first margin data can be first stored margin data that is retrieved from storage.

Block 704 can obtain second margin data relating to the component from a subsequent second time. Note that the component may be positioned in the same platform during both the first and second times. Alternatively, the component may be positioned on a first platform at the first time and on a second platform at the second time.

In some cases, obtaining first margin data and second margin data can entail obtaining margin that is stored at the first time and at the second time. Margin data also can be stored each time physical layer margin training is performed on the component. In some cases, the margin data includes or is associated with information relating to a platform on which the component was positioned for the margin testing and parameters associated with the testing, such as temperature.

In some implementations, the method both stores the margin data and then receives the stored margin data. In other cases, one method generates and stores the margin data and another method retrieves and analyzes the stored margin data.

Block 706 can compare the first margin data to the second margin data to identify a change in a condition of the component. Note that the change in condition can be a change in condition which has occurred between the first time and the second time. Alternatively, the change in condition can be a predicted change that is likely to happen in the future based upon changes between the first margin data and the second margin data.

The order in which the methods are described is not intended to be construed as a limitation, and any number of the described acts can be combined in any order to implement the method, or an alternate method. The method can be accomplished by the systems and devices described above. In some cases, the method is accomplished by executing code (e.g., software or firmware). In some configurations, the code is stored as computer-readable instructions that are stored on memory and/or storage (e.g., storage media) and executed by a processor. The processor can be one of the processing elements described above or a different processor.

### Additional Examples

Various examples are described above. Additional examples are described below. One example includes a system comprising a memory unit and storage persistently storing first margin data from physical layer training of the memory unit at a first time and second margin data from physical layer training of the memory unit at a subsequent second time.

Another example can include any of the above and/or below examples where the memory unit is a dynamic random access memory (DRAM) memory unit or wherein the memory unit is a dual in-line memory module (DIMM) that comprises multiple DRAM memory units.

Another example can include any of the above and/or below examples where the storage is on a package associated with the memory unit.

Another example can include any of the above and/or below examples where the storage is remote from the memory unit, and wherein the storage associates the first margin data and the second margin data with a unique identifier of the memory unit.

Another example can include any of the above and/or below examples where the storage associates other margin data with unique identifiers of other memory units.

Another example can include any of the above and/or below examples where the storage comprises a database, and wherein the first margin data includes information relating to a first platform that the memory unit was associated with when the first margin data was gathered, and wherein the first margin data includes information relating to a second platform that the memory unit was associated with when the second margin data was gathered.

Another example can include any of the above and/or below examples where the first platform is the same as the second platform or wherein the first platform is different than the second platform.

Another example can include any of the above and/or below examples where the first platform comprises a test platform and the second platform comprises a production platform.

Another example includes a device-implemented method comprising obtaining first margin data relating to a component from a first time, obtaining second margin data relating to the component from a subsequent second time, and comparing the first margin data to the second margin data to identify a change in a condition of the component.

Another example can include any of the above and/or below examples where the obtaining first margin data and obtaining second margin data comprises retrieving stored first margin data and stored second margin data.

Another example can include any of the above and/or below examples where the stored first margin data comprises information relating to a platform on which the component is positioned.

Another example can include any of the above and/or below examples where the obtaining first margin data and obtaining second margin data comprises generating the first margin data and the second margin data.

Another example can include any of the above and/or below examples where the generating comprises generating the first margin data and the second margin data during physical layer training of the component.

Another example can include any of the above and/or below examples where the generating the first margin data comprises generating the first margin data with the component positioned on a first platform and generating the second margin data with the component positioned on the first platform.

Another example can include any of the above and/or below examples where the generating the first margin data comprises generating the first margin data with the component positioned on a first platform and generating the second margin data with the component positioned on a different second platform.

Another example can include any of the above and/or below examples where the change in a condition of the component comprises a change in a condition which has already occurred at the second time.

Another example can include any of the above and/or below examples where the change in a condition of the component comprises a change in a condition which has not occurred at the second time.

Another example can include any of the above and/or below examples where the change in a condition of the component comprises a future change in a condition which is predicted to occur after the comparing.

Another example can include any of the above and/or below examples where the method further comprises training an artificial intelligence model with the first margin data, the second margin data and the identified change in a condition of the component.

Another example includes a DIMM comprising a package holding multiple DRAM units connected to a physical layer interface, a controller configured to perform margin testing on the DRAM units and the physical layer interface, and persistent storage configured to store margin data from each margin testing performed by the controller on the DRAM units for a lifetime of the DIMM.

Another example can include any of the above and/or below examples where the system is implemented on the package and the package comprises the DIMM or wherein the system is implemented on a platform that includes the package.

### Conclusion

The description relates to detecting changes in component health from stored margin data. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims and other features and acts that would be recognized by one skilled in the art are intended to be within the scope of the claims.

1. A device, comprising:
a memory unit; and,
storage persistently storing first margin data from physical layer training of the memory unit at a first time and second margin data from physical layer training of the memory unit at a subsequent second time.

2. The device of claim 1, wherein the memory unit is a dynamic random access memory (DRAM) memory unit or wherein the memory unit is a dual in-line memory module (DIMM) that comprises multiple DRAM memory units.

3. The device of claim 1, wherein the first margin data defines bounds of a first margin eye and the second margin data defines bounds of a second margin eye.

4. The device of claim 1, wherein the storage comprises nonvolatile random access memory (NVRAM).

5. The device of claim 1, wherein the storage associates other stored margin data with unique identifiers of other memory units on the device.

6. The device of claim 1, wherein the storage comprises a database, and wherein the first margin data includes information relating to a first platform that the memory unit was associated with when the first margin data was gathered, and wherein the second margin data includes information relating to a second platform that the memory unit was associated with when the second margin data was gathered.

7. The device of claim 6, wherein the first platform is different than the second platform.

8. The device of claim 7, wherein the first platform comprises a test platform and the second platform comprises a production platform.

9. A device-implemented method, comprising:
obtaining stored first margin data relating to double data rate (DDR) memory physically positioned on a component, the stored first margin data relating to first margin testing of the DDR memory at a first time and persistently stored on the component;
obtaining second margin data relating to the DDR memory physically positioned on the component, the second margin data relating to second margin testing of the DDR memory at a subsequent second time; and,
comparing the first margin data to the second margin data to identify a change in a condition of the DDR memory physically positioned on the component.

10. The method of claim 9, wherein obtaining second margin data comprises generating the second margin data by performing the second margin testing.

11. The method of claim 9, wherein the comparing comprises comparing bounds of a first margin eye defined by the first margin data to bounds of a second margin eye defined by the second margin data and to a threshold.

12. The method of claim 11, wherein the comparing identifies the change in the condition as a shift between the bounds of the first margin eye and the bounds of the second margin eye toward the threshold.

13. The method of claim 12, wherein the condition of the component is faulty when either of the bounds of the first margin eye and the bounds of the second margin eye exceed the threshold, and wherein the shift between the bounds of the first margin eye and the bounds of the second margin eye toward the threshold is indicative of a future time when the component will become faulty.

14. The method of claim 13, further comprising predicting the future time when the component will become faulty based on the shift.

15. The method of claim 14, wherein the predicting is further based upon conditions at which the first margin data and the second margin data were obtained, and wherein the conditions are stored with the first margin data and the second margin data.

16. The method of claim 9, wherein the change in a condition of the component comprises a change in a condition which has already occurred at the subsequent second time.

17. The method of claim 9, wherein the change in a condition of the component comprises a change in a condition which has not occurred at the subsequent second time.

18. The method of claim 9, wherein the change in a condition of the component comprises a future change in a condition which is predicted to occur after the comparing.

19. The method of claim 9, further comprising training an artificial intelligence model with the stored first margin data, the second margin data, and the identified change in a condition of the component.

20. A system, comprising:
a package holding multiple DRAM units connected to a physical layer interface;
a controller configured to perform margin testing on the DRAM units and the physical layer interface; and,
persistent storage storing margin data from each margin testing performed by the controller on the DRAM units for a lifetime of the DRAM units.
